(19) United States
(12) Patent Application Publication
(10) Pub. No.: US 2009/0170269 A1
(43) Pub. Date: Jul. 2, 2009

(54) HIGH VOLTAGE MOSFET DEVICES CONTAINING TIP COMPENSATION IMPLANT

(76) Inventor: Ranadeep Dutta, Campbell, CA (US)

Correspondence Address: INTEL CORPORATION;c/o CPA Global, P.O. BOX 52050, MINNEAPOLIS, MN, 55402, US

(21) Appl. No.: 11/968,135

(22) Filed: Dec. 31, 2007

(51) Int. Cl. H01L 21/336

(52) U.S. Cl. 438/289; 257/E21.409

(57) ABSTRACT

Semiconductor devices and methods for making semiconductor devices are described in this application. The semiconductor devices comprise a MOSFET device in a semiconductor substrate, with the MOSFET device containing source and drain regions with a tip implant region near the surface of the substrate. The tip implant region contains a tip compensation implant region located under the gate of the MOSFET device that overlaps with the source and drain. The tip compensation implant region reduces the dopant concentration in this gate-drain overlap region, while maintaining a graded drain-well junction profile, thereby reducing the band to band tunneling and increasing the drain breakdown voltage. Other embodiments are described.

### FIELD

The application relates to semiconductor devices and methods for making semiconductor devices.

### BACKGROUND

Semiconductor devices are built in semiconductor materials, typically silicon wafers (or substrates), through a series of processes. These processes modify the silicon wafer by building components of the semiconductor devices in the wafer. One type of semiconductor device, a field effect transistor (FET), is made by implanting elements (or dopants) to change the conductivity of the silicon material of the substrate, thereby creating source and drain regions. B can be used as a p-type dopant to improve the flow of positive charge (holes) and As and P can be used as an n-type dopant to improve the flow of negative charge (electrons). A channel of oppositely-doped silicon in the substrate separates the source and drain regions. On the surface of the substrate above the channel and between the source and drain regions a thin dielectric layer (silicon oxide—SiO₂) can be sandwiched between a conductive layer (polysilicon or metal) and the channel within the substrate. The conductive layer forms the gate of the semiconductor device and the dielectric between the gate and channel (called a gate dielectric) only allows a small amount of current to flow through the gate. A voltage on the gate of the transistor exceeding a threshold voltage allows a current to flow through the channel from the source to the drain or from the drain to the source. Because of the materials used, one common type of transistor is the metal-oxide-semiconductor field effect transistor or MOSFET.

### BRIEF DESCRIPTION OF THE DRAWINGS

The following description can be better understood in light of the Figures, in which:

FIGS. 1-5 illustrate parts of the process that can be used to manufacture MOSFET devices in some embodiments;

FIG. 6 contains a graph comparing the electrical characteristics of the MOSFET devices formed by the process depicted in FIGS. 1-5 with other MOSFET devices;

FIG. 7 illustrates a concentration profile of the MOSFET devices taken in the direction A for the embodiments of the MOSFET devices shown in FIG. 5; and

FIG. 8 illustrates a concentration profile of the MOSFET devices taken in the direction B for the embodiments of the MOSFET devices shown in FIG. 5.

The Figures illustrate specific aspects of the semiconductor devices and associated methods of making and using such devices. Together with the following description, the Figures demonstrate and explain the principles of the semiconductor devices and associated methods. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and methods for making and using such device can be implemented and used without employing these specific details. For example, while the description below focuses on MOSFET device, this process can be applied to form any other type of semiconductor device. Indeed, the description can be modified to be used in other electrical devices that are formed using similar methods.

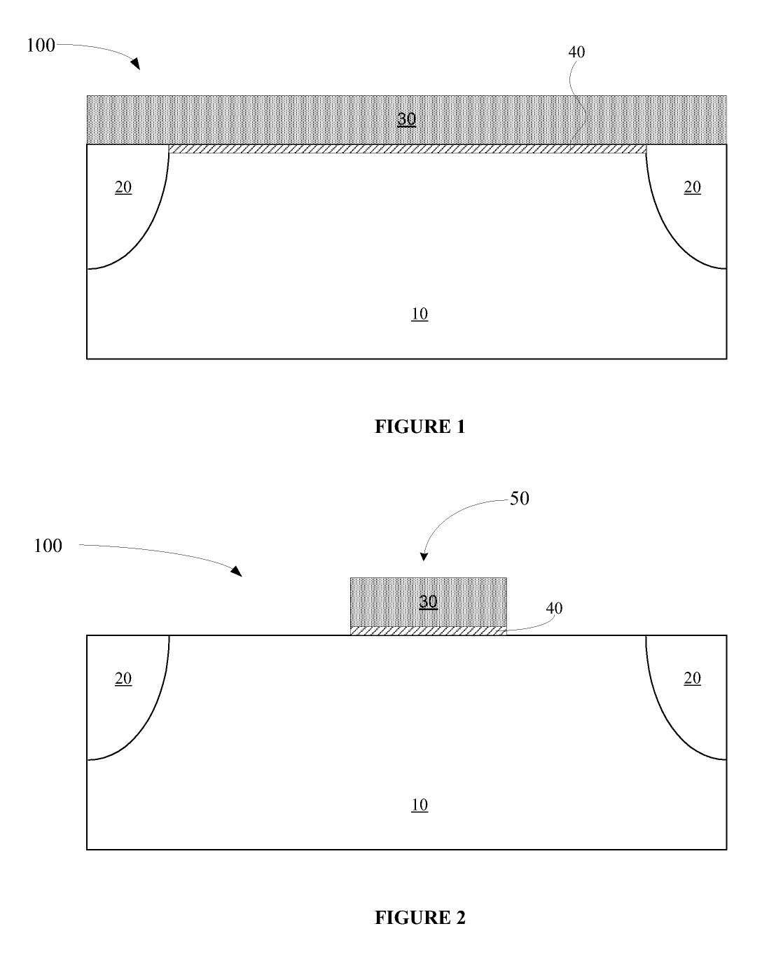

FIGS. 1-5 illustrates an exemplary process that can be used to form a MOSFET device 100. In some embodiments, the MOSFET transistor can be an n-channel FET (nFET, n-type FET, n-p-n FET, or NMOS) or p-channel (pFET, n-type FET, p-n-p FET, or p-channel metal-oxide semiconductor (PMOS). For example, an n-channel FET can have source and drain regions doped with an n-type doping on a p-type doped substrate (or well). The channel formed between the source and drain is doped with a p-type doping. For a p-channel or p-type FET, the source and drain regions are doped with a p-type doping on a n-type doped substrate or well forming an n-doped channel between the source and drain. When both n-channel and p-channel FET transistors are utilized on the same silicon substrate, the FET transistors form a complementary metal-oxide semiconductor (CMOS) device. If the substrate is doped with a p-type doping, an n-type doped well can be used to form a p-channel FET for a CMOS circuit. If the substrate is doped with an n-type doping, a p-type doped well can be used to form n-channel FET for a CMOS circuit.

Beginning in FIG. 1, this process by providing a substrate 10. Any substrate known in the art can be used, including silicon wafers, epitaxial Si layers, polysilicon layers, bonded wafers such as used in silicon-on-insulator (SOI) technologies, and/or amorphous silicon layers, all of which may be doped or undoped. If the substrate is undoped, it can then be implanted with any desired type of dopant to the concentration needed by any method known in the art. In some embodiments, an n-type dopant is implanted in the substrate 10 to form a n-well. If the substrate 10 does not contain an epitaxial Si layer, such a layer can be formed on the substrate 10 as known in the art.

Next, the isolation regions 20 are formed in the substrate 10. Isolation regions 20 are used to isolate one semiconductor device from another in the substrate 10, i.e., to isolate one MOSFET device 100 from another MOSFET device formed on an adjacent part of the substrate 10. In some embodiments, the isolation regions 20 are field oxide regions that can be formed using any process known in the art.

Then, a thin insulating layer 40 is formed on the upper surface of the substrate 10. This material for the insulating layer 40 can be any high-quality insulating material known in the art, such as silicon nitride, silicon oxide, or silicon oxynitride. In some embodiments, the insulating layer is silicon oxide that is formed by oxidizing the Si substrate or depositing an oxide layer using any processes known in the art.

Then, as shown in FIG. 1, a conducting layer 30 is formed on the insulating layer 40. The material for the conducting layer 30 can be any known material that can operate as a gate conductor in the MOSFET device 100, including metal, metal alloy, or polysilicon. In some embodiments, polysilicon is used as the material for the gate conducting layer 30. The conducting layer can be deposited using any process known in the art, including sputtering processes and physical or chemical vapor deposition processes. Optionally, the conductive layer 30 can be doped with any suitable dopant to the desired concentration, particularly when the conductive layer is polysilicon. In some embodiments, the dopant is a p-type dopant that is implanted to form a p+ gate conducting layer.

As shown in FIG. 2, a gate structure 50 is formed by removing portions of the conducting layer 30 and the dielectric layer 40. The unwanted portions of these two layers can be removed using any known process, including any mask and etch process. The remaining portions of these two layers then form the gate conductor and the gate dielectric of the MOSFET device 100.

Next, so shown in FIG. 3, a first dopant region 60 (or a tip compensation implant region) is formed in the substrate 10. The first dopant region 60 can be formed by implanting a first dopant at an energy and a dose sufficient to form the first dopant region 60 to the desired concentration. In some embodiments, the first dopant is an n-type dopant that is implanted at a concentration that allows the tip compensation implant to operate as described herein. For example, where the first dopant comprises As, it can be implanted at an energy ranging from about 5 to about 50 keV, at a dose ranging from about 1.0×10¹² to about 1.0×10¹⁴ atoms/cm². In other embodiments, the As can be implanted in the substrate at an energy of about 10 keV and a dose of about 1.5×10¹³ atoms/cm². Of course, other energies could be used to obtain any desired concentration.

Next, as shown in FIG. 3, a second dopant region 70 (i.e., the source/drain extension or tip implant region) is formed in the substrate 10. The dopant used as the second dopant will partly depend on the dopant used as the first dopant. In some embodiments, the second dopant is a p-type dopant. For example, where As is used as the first dopant, B can be used as the second dopant. The second dopant region 70 can be formed by implanting the second dopant at an energy and a dose sufficient to implant the second dopant to the desired concentration. In some embodiments where B is used as the second dopant, it can be implanted at an energy ranging from about 10 to about 50 keV at a dose ranging from about 5.0×10¹² to about 1.0×10¹⁵ atoms/cm². In other embodiments, B can be implanted in the substrate at an energy of about 25 keV and a dose of about 1.5×10¹³ atoms/cm². Of course, other energies could be used to obtain any desired concentration.

As shown in FIG. 4, the methods for making MOSFET device 100 continues when a spacer 80 is then formed on the sidewalls of the gate structure 50. The spacer 80 comprises any known dielectric or insulating material, including those mentioned above. The spacer 80 can be formed using any known process in the art, including deposition of a silicon oxide layer followed by an etch process to leave portions of that SiO2 layer remaining on the sidewalls of the gate structure 50.

After formation of the spacer 80, a third dopant region 90 (or source/drain region) is formed. Because of the presence of the spacer 80, the third dopant region 90 will be smaller than both the first and second dopant regions. The dopant used as the third dopant will partly depend on the dopant used as the first and second dopant. In some embodiments, the third dopant is a p type dopant. For example, where As is used as the first dopant and B is used as the second dopant, B can be used as the third dopant. The third dopant region can be formed by implanting a third dopant at an energy and a dose sufficient to form the third dopant region to the desired concentration.

As shown in FIG. 5, all 3 of the aforementioned implants are annealed and diffused into the substrate 10. In some embodiments, this is achieved by a rapid thermal annealing (RTA) process. The RTA process drives the dopants from the second region deeper into the substrate 10 and form the source and drain 110. Accordingly, the RTA process can be performed for any time and temperature sufficient to achieve this result.

After the above processes are concluded, any further semiconductor processing can be carried out. For example, other processing needed to complete other parts of the semiconductor device can then be carried out, as known in the art. For example, this processing can include the formation of interlevel dielectic layers and metal lines.

The finished MOSFET device 100 is illustrated in FIG. 5. This device contains a tip compensation region 120 that results from the formation of the shallow, first dopant region 60. The tip compensation region 120 contains an opposite type of dopant than the source and drain regions 110 and so lower the dopant concentration in these regions of the source and drain. This configuration contributes to increasing the voltage limit of the MOSFET device 100 in the following manner. The voltage limit of a MOSFET device depends, in part, on the gated diode breakdown phenomena which can be impacted by two mechanisms. First, the junction avalanche breakdown voltage (BV) occurring at the P+ NWell junction (for a PMOS) with an electric field parallel to the Si surface. Second, the band to band tunneling (BTBT) that is the cause for gate-induced drain leakage (GIDL) occurring in the depletion region of the tip under the gate and which has an electric field vertical to their interface.

Other methods of increasing the voltage limit of MOSFET devices impacted only the first mechanism. Therefore, these methods had no impact on the gated edge dominated junction leakage, a significant contributor to the standby mode power dissipation. Also, these methods caused a significant increase of the overlap capacitance, increased sub-threshold leakage, and impaired the transistor scaling & feature size reduction due to the deeper tip junction.

The methods described in FIGS. 1-5 can increase the BVD and decrease ICCS through a reduction in the second mechanism. In some embodiments, the BVD voltage can be increased up to about 240 mV. The methods achieve a reduced doping concentration in the gate-drain overlap region, without impacting the tip-well junction curvature that dictates the avalanche BV. A shallow implant can be used to form the first dopant region 60 and can be tailored to compensate for the high concentration of the dopants under the gate oxide edge which overlaps the drain. The high concentration in this drain-gate overlap region can contribute to the BTBT that reduces the high voltage capability of the MOSFET. Reducing the dopant concentration in this gate-drain overlap region, while maintaining a graded drain-well junction profile, can diminish the induced doping under the gate edge and, thereby, reduce the BTBT.

The graded drain-well junction profile and reduced dopant concentration in this gate-drain overlap region can be achieved through by the oppositely-doped first dopant region 60 that remains shallower than the third dopant region 80 so it does not impact the tip-well junction curvature. In other words, the tip compensation implant (formed from the first dopant region 60) precedes the tip implant (formed from the third dopant region 90) in sequence, is shallower than the tip implant, and tailored to counter-dope the source-drain induced high doped region under the gate edge. As a result, the implant energy and dose needed to form the second dopant regions (that will form the source and drain) is reduced, in order to adequately compensate the oppositely and heavily-doped source/drain atoms moving across the spacer width through lateral straggle and side diffusion.

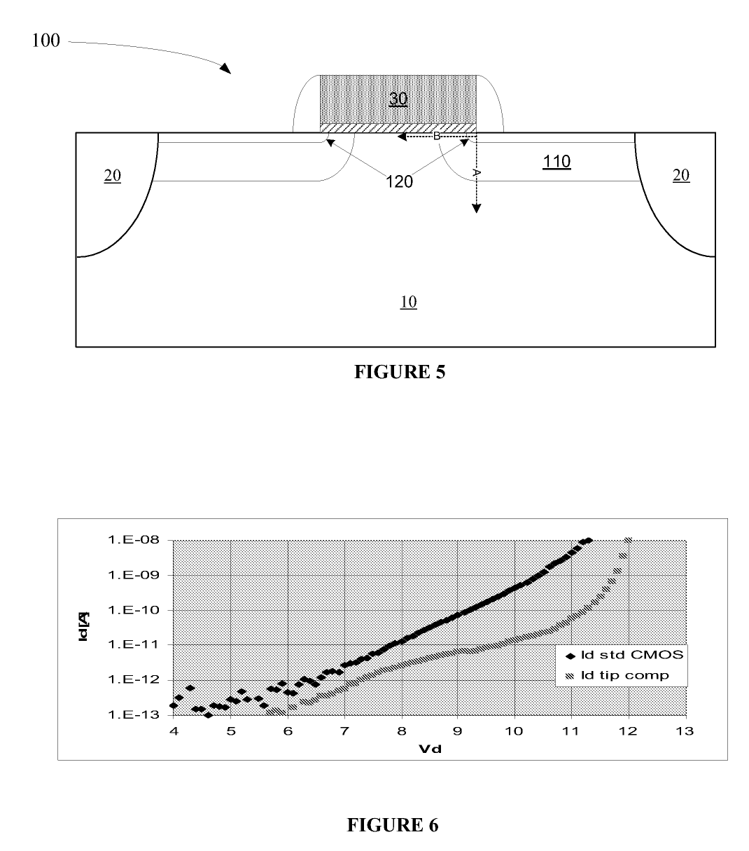

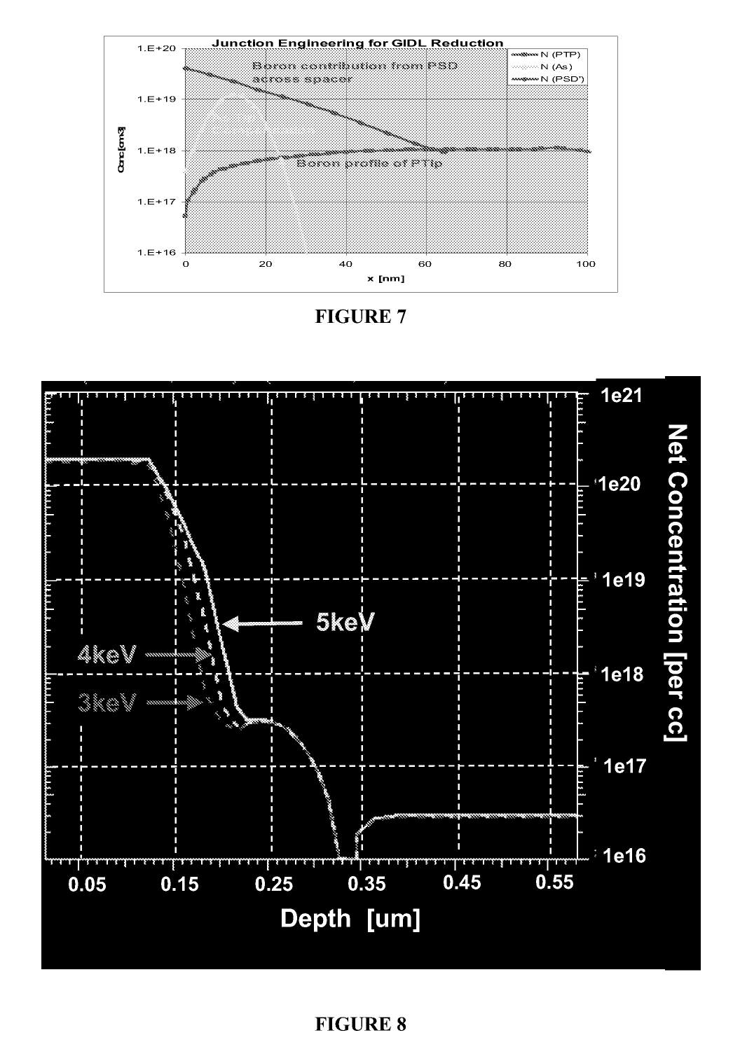

The high concentration in the gate-drain overlap region in other CMOS devices comes primarily from the heavy source-drain implant reaching across the spacer and to a smaller extent from the tip implant. The contributions are illustrated in FIG. 7, which shows the concentration profiles of the device in FIG. 5 taken in the direction A. As illustrated in FIG. 7, this high concentration causes high vertical electrical field in the gate-drain overlap region, causing increased amounts of the second mechanism mentioned above. This effect reduces the high voltage capability of CMOS and increases standby leakage. But the shallow tip compensation implant reduces the net doping in the gate-drain overlap region, as shown in FIG. 7, significantly reducing the BTBT, thus providing higher voltage capability and significantly reducing the standby power dissipation. FIG. 8 illustrates the concentration profiles of the MOSFET device 100 in FIG. 5 taken in the direction B.

In some embodiments, the tip compensation implant conditions can be optimized to enhance the MOSFET device characteristics. In these embodiments, the conditions of the tip compensation implant can be on the same order as the conditions of the tip implant, yet at an energy which allows the tip compensation implant to be shallower and more tightly distributed than the tip implant. This configuration of the implant conditions can significantly compensate the laterally diffused source/drain profile shown in FIG. 7, without causing any counterdoping.

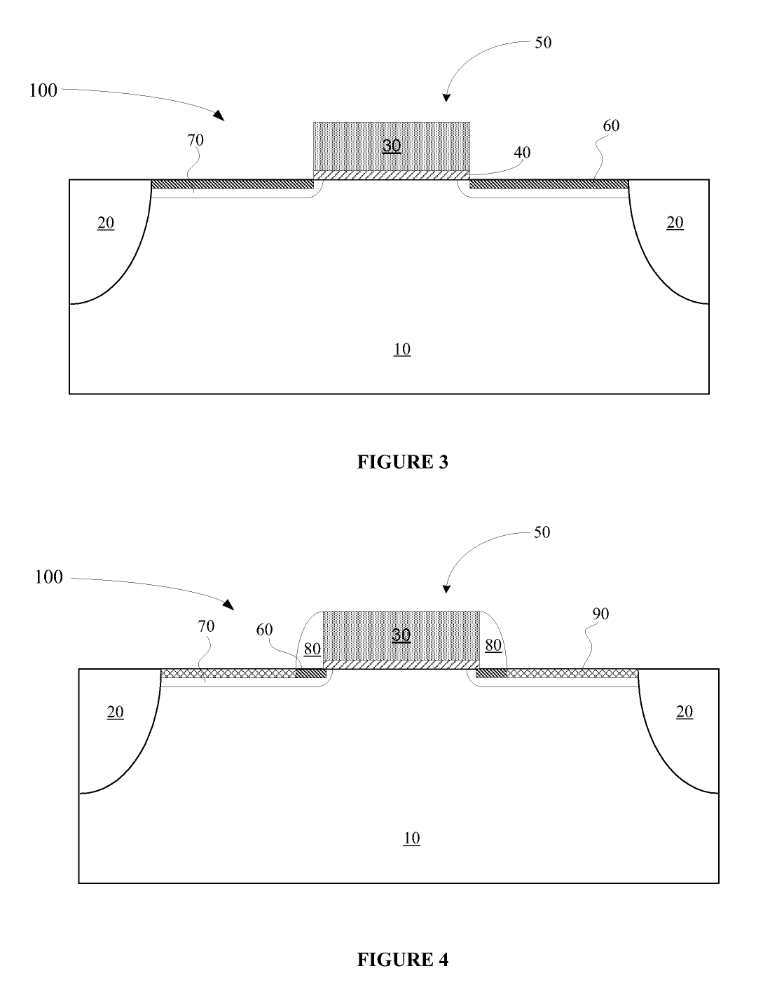

An example of the voltage characteristics of the MOSFET devices 100 is illustrated in FIG. 6. In that Figure, the Id-Vd curve shows a curve that is charactreristic of the tip compensation region 120, which significantly reduces the GIDL slope at higher voltages, i.e., those voltage approaching breakdown. This characteristic is shown by the pink curve in FIG. 6 which compares favorably with the existing devices (represented by the blue curve) where the GIDL region is characterized by a constant log Id-Vd slope that depends on the gate dielectric thickness. Accordingly, the MOSFET devices 100 are able to reduce the band to band tunneling (BTBT) and decrease the overlap capacitance while increasing the drain breakdown voltage (BVD), yet without compromising the gate scaling and reducing standby current.

Having described the preferred aspects of the semiconductor devices and associated methods, it is understood that the appended claims are not to be limited by particular details set forth in the above description, as many apparent variations thereof are possible without departing from the spirit or scope thereof.

1. A process for making a semiconductor device, comprising:
providing a semiconductor substrate with an isolation region;
providing a gate dielectric and a gate conductor on the substrate;
implanting a first dopant to a first depth in the substrate in a first region between the isolation region and the gate conductor;
implanting a second dopant in the substrate to a second depth that is greater than the first depth;
forming a spacer on the sidewalls on the gate conductor;
implanting a third dopant in the substrate in a second region that is smaller than the first region; and annealing the resulting structure.

2. The process of claim 1, wherein the semiconductor device comprises a MOSFET device.

3. The process of claim 1, wherein the first dopant comprises As and is implanted at an at an energy ranging from about 5 to about 50 keV and at a dose ranging from about 1.0×10¹² to about 1.0×10¹⁴ atoms/cm².

4. The process of claim 3, wherein the first dopant comprises As and is implanted at an energy of about 10 keV and a dose of about 1.5×10¹³ atoms/cm².

5. The process of claim 1, wherein the second dopant comprises B and is implanted at an energy ranging from about 10 to about 50 keV at a dose ranging from about 5.0×10¹² to about 1.0×10¹⁵ atoms/cm².

6. The process of claim 5, wherein the second dopant comprises B and is implanted in the substrate at an energy of about 25 keV and a dose of about 1.5×10¹³ atoms/cm².

7. The process of claim 2, wherein the annealing process drives the second dopant into the substrate to form source and drain regions of the MOSFET.

8. The process of claim 5, wherein the first dopant reduces the dopant concentration in the drain region underlying the gate while maintaining the dopant profile at the interface of the drain and the substrate.

9. A semiconductor device made by the method comprising:
providing a semiconductor substrate with an isolation region;
providing a gate dielectric and a gate conductor on the substrate;
implanting a first dopant to a first depth in the substrate in a first region between the isolation region and the gate conductor;
implanting a second dopant in the substrate to a second depth that is greater than the first depth;
forming a spacer on the sidewalls on the gate conductor;
implanting a third dopant in the substrate in a second region that is smaller than the first region; and annealing the resulting structure.

10. The semiconductor device of claim 9, wherein the semiconductor device comprises a MOSFET device.

11. The semiconductor device of claim 9, wherein the first dopant comprises As and is implanted at an at an energy ranging from about 5 to about 50 keV and at a dose ranging from about 1.0×10¹² to about 1.0×10¹⁴ atoms/cm².

12. The semiconductor device of claim 11, wherein the first dopant comprises As and is implanted at an energy of about 10 keV and a dose of about 1.5×10¹³ atoms/cm².

13. The semiconductor device of claim 9, wherein the second dopant comprises B and is implanted at an energy ranging from about 10 to about 50 keV at a dose ranging from about 5.0×10¹² to about 1.0×10¹⁵ atoms/cm².

14. The semiconductor device of claim 13, wherein the second dopant comprises B and is implanted in the substrate at an energy of about 25 keV and a dose of about 1.5×10¹³ atoms/cm².

15. The semiconductor device of claim 10, wherein the annealing process drives the second dopant into the substrate to form source and drain regions of the MOSFET.
